(19) United States
(12) Patent Application Publication
(10) Pub. No.: US 2009/0128198 A1
(43) Pub. Date: May 21, 2009

(54) DIGITAL FREQUENCY SYNTHESIZER

(75) Inventors: Franck Badets, Voiron (FR); Thomas Finateu, Grenoble (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.A., Montrouge (FR)

(21) Appl. No.: 12/254,617

(22) Filed: Oct. 20, 2008

(30) Foreign Application Priority Data
Oct. 22, 2007 (FR) 07/58456

(51) Int. Cl. H03B 21/00

(52) U.S. Cl. 327/107; 327/105

(57) ABSTRACT

A digital frequency synthesizer receiving a first signal corresponding to a periodic sequence of first pulses at a first frequency and providing a second signal corresponding to a periodic sequence of second pulses at a second frequency. The synthesizer includes a first circuit clocked by a third signal corresponding to a sequence of third pulses and obtained from the first signal, the first circuit providing a fourth digital signal which, for any set of third successive pulses, increases (decreases) on each pulse and decreases (increases) at the end of said set; and a second circuit receiving the first and fourth signals and providing, for each first pulse from among some at least of the first pulses, a second pulse which is shifted with respect to the first pulse by a duration which depends on the fourth signal.

### CROSS REFERENCE TO RELATED APPLICATIONS

This application claims the priority benefit of French patent application number 07/58456, filed on Oct. 22, 2007, entitled “Digital Frequency Synthesizer,” which is hereby incorporated by reference to the maximum extent allowable by law.

### BACKGROUND OF THE INVENTION

1. Field of the Invention

The present application relates to a frequency synthesizer capable of providing, from a first periodic signal at a first frequency, a second periodic signal at a second frequency different from the first frequency, where the ratio between the first and second frequencies can be modified.

2. Discussion of the Related Art

Many electronic circuits use one or several frequency synthesizers. As an example, telecommunication systems generally use frequency synthesizers which provide periodic signals in determined frequency bands to modulate the signals to be transmitted. In mobile telephony, the DCS (Digital Communication System) standard for example provides the transmission of signals having a frequency on the order of 1,800 MHz. Telecommunication systems using ISM (Industrial Scientific and Medical) frequency bands transmit, for example, signals at frequencies on the order of 2.4 GHz.

An example of a conventional frequency synthesizer uses a phase-locked loop. A disadvantage of such a frequency synthesizer is that it exhibits, in operation, a generally non-negligible latency which corresponds to the duration required to stabilize the phase-locked loop. Further, such a synthesizer is essentially formed of analog circuits, which makes a modification of the synthesizer difficult. Further, the phase-locked loop generally comprises one or several filters, which may be difficult to form.

There exist frequency synthesizers which provide, from a first signal corresponding to a periodic sequence of pulses at a first frequency, a second signal corresponding to a periodic sequence of pulses at a second frequency, where the ratio between the first and second frequencies can be modified. Such synthesizers are generally called digital frequency synthesizers and may essentially be formed of logic gates, especially based on MOS transistors. They however generally have the disadvantage that they have a large power consumption and that they can only operate at low frequencies.

An example of a digital frequency synthesizer uses a phase accumulator. A phase accumulator is a circuit clocked by a clock signal and providing a signal corresponding to a non-perfectly periodic sequence of pulses at an average frequency proportional to the clock frequency and which corresponds to the desired frequency. However, since the signal provided by the phase accumulator is not perfectly periodic, the frequency synthesizer further comprises a correction circuit which, based on the pulse sequence provided by the phase accumulator, provides a periodic sequence of pulses corrected to the desired frequency. A disadvantage of this type of frequency synthesizer is that it cannot generally provide a signal having a frequency greater than half the clock frequency.

The significant power consumption of a conventional digital frequency synthesizer results in that, when used in battery-powered systems, it is necessary to search for a compromise between the power consumption and the clock frequency that can be used to clock the synthesizer.

### SUMMARY OF THE INVENTION

There is a need for a digital frequency synthesizer using a phase accumulator and capable of providing, from a first periodic sequence of pulses at a first frequency, a second periodic sequence of pulses at a second frequency which may be lower than, equal to, or greater than the first frequency.

According to an embodiment, there is provided a digital frequency synthesizer receiving a first signal corresponding to a periodic sequence of first pulses at a first frequency and providing a second signal corresponding to a periodic sequence of second pulses at a second frequency. The synthesizer comprises a first circuit clocked by a third signal corresponding to a sequence of third pulses and obtained from the first signal, the first circuit providing a fourth digital signal which, for any set of third successive pulses, increases on each pulse and decreases at the end of said set or decreases on each pulse and increases at the end of said set; and a second circuit receiving the first and fourth signals and providing, for each first pulse from among some at least of the first pulses, a second pulse which is shifted with respect to the first pulse by a duration which depends on said fourth signal.

According to an embodiment, the second circuit comprises a third circuit providing a fifth analog signal which depends on the fourth signal; a source of a sixth analog signal; and a comparator receiving the fifth and sixth signals and providing the second signal.

According to an embodiment, the first and third signals are identical. The source is capable of providing the sixth analog signal in the form of a first sawtooth voltage at the clock rate of the first signal. The third circuit comprises a digital-to-analog converter providing, at the clock rate of the first signal, the fifth signal in the form of a second stepped voltage which depends on the fourth signal.

According to an embodiment, the source is capable of providing the sixth signal in the form of a constant voltage. The third circuit comprises a digital-to-analog converter providing a current which at least partly depends on the fourth signal; a capacitor charged by the current; and a switch assembled in parallel across the capacitor, the fifth signal corresponding to the voltage across the capacitor.

According to an embodiment, the synthesizer comprises a finite state machine clocked by the first signal and capable of controlling, in a first state, the turning-on of the switch to discharge the capacitor; and causing, in a second state, the turning-off of the switch and causing the converter to charge the capacitor with said current.

According to an embodiment, the first circuit comprises a first storage unit providing, at the clock rate of the third signal, a seventh digital signal; an adder receiving the seventh digital signal and an eighth signal and providing a ninth digital signal corresponding to the sum of the seventh and eighth signals; and a second storage unit receiving the ninth signal and providing, at the rate of the third signal, the eighth signal which corresponds to the last value of the stored ninth signal, the fourth signal being obtained from the eighth signal.

According to an embodiment, the first circuit comprises a first storage unit providing, at the clock rate of the third signal, a seventh digital signal; a first adder receiving the seventh digital signal and an eighth signal and providing a ninth digital signal corresponding to the sum of the seventh and eighth signals; a second adder receiving the seventh signal, the eighth signal and a tenth digital signal, the tenth signal corresponding to a constant value, the second adder providing an eleventh signal corresponding to the sum of the seventh, eighth, and tenth signals; a multiplexer receiving the eighth terminal and the eleventh signal and comprising a selection signal receiving a twelfth signal provided by the finite state machine and providing a thirteenth signal equal to the eighth signal or to the eleventh signal according to the value of the twelfth signal; and a second storage unit receiving the thirteenth signal and providing, at the rate of the third signal, the eighth signal which corresponds to the last value of the stored thirteenth signal, the fourth signal being obtained from the eighth signal.

According to an embodiment, the second circuit comprises N current sources, N being an integer corresponding to a power of two, each current source providing a current which depends on the fourth signal; and at least N transistors, each transistor having a first main terminal connected to one of the N current sources and a second main terminal connected to an output node, the transistor being controlled by one of N oscillating signals, the N oscillating signals being phase-shifted with respect to one another, the second signal being provided to said output node.

An embodiment also provides a method for providing, from a first signal corresponding to a periodic sequence of first pulses at a first frequency, a second signal corresponding to a periodic sequence of second pulses at a second frequency. The method comprises the steps of providing, at the clock rate of a third signal corresponding to a sequence of third pulses and obtained from the first signal, and providing a fourth digital signal which, for any set of third successive pulses, increases on each pulse and decreases at the end of said set; and of providing, for each first pulse from among some at least of the first pulses, a second pulse shifted with respect to said first pulse by a duration which depends on the fourth signal.

According to an embodiment, the method further comprises the steps of providing a fifth analog signal which depends on the fourth signal; and providing the second signal based on the comparison of the fifth signal and of a sixth analog signal.

According to an embodiment, the method further comprises the steps of converting the fourth signal into a current; and charging a capacitor with said current, the fifth signal corresponding to the voltage across the capacitor and the sixth signal being a constant voltage.

The foregoing and other objects, features, and advantages will be discussed in detail in the following non-limiting description of specific embodiments in connection with the accompanying drawings.

### BRIEF DESCRIPTION OF THE DRAWINGS

FIG. 1 schematically shows a conventional example of a phase accumulator;

FIG. 2 shows an example of the variation of characteristic signals of the phase accumulator of FIG. 1;

FIG. 3 schematically shows a conventional example of a digital frequency synthesizer using the phase accumulator of FIG. 1;

FIG. 4 schematically shows an embodiment of a digital frequency synthesizer;

FIG. 5 shows an example of the variation of characteristic signals of the synthesizer of FIG. 4;

FIG. 6 shows another embodiment of a digital frequency synthesizer;

FIG. 7 shows an example of the variation of characteristic signals of the synthesizer of FIG. 6;

FIG. 8 shows another embodiment of a digital frequency synthesizer;

FIG. 9 shows an example of the variation of characteristic signals of the synthesizer of FIG. 8;

FIGS. 10 and 11 show other embodiments of digital frequency synthesizers;

FIG. 12 shows a more detailed embodiment of the phase accumulator of the frequency synthesizer of FIG. 11;

FIG. 13 illustrates the states taken by the finite state machine of the synthesizer of FIG. 11;

FIG. 14 shows an example of the variation of characteristic signals of the synthesizer of FIG. 11;

FIG. 15 shows another embodiment of a digital frequency synthesizer;

FIG. 16 illustrates the operation of the synthesizer of FIG. 15; and

FIG. 17 shows another embodiment of a digital frequency synthesizer.

### DETAILED DESCRIPTION

For clarity, the same elements have been designated with the same reference numerals in the different drawings.

The frequency synthesizer according to an embodiment uses a phase accumulator that can have a conventional structure or a structure slightly modified with respect to a conventional structure. The structure and the operation of a conventional phase accumulator will thus first be described.

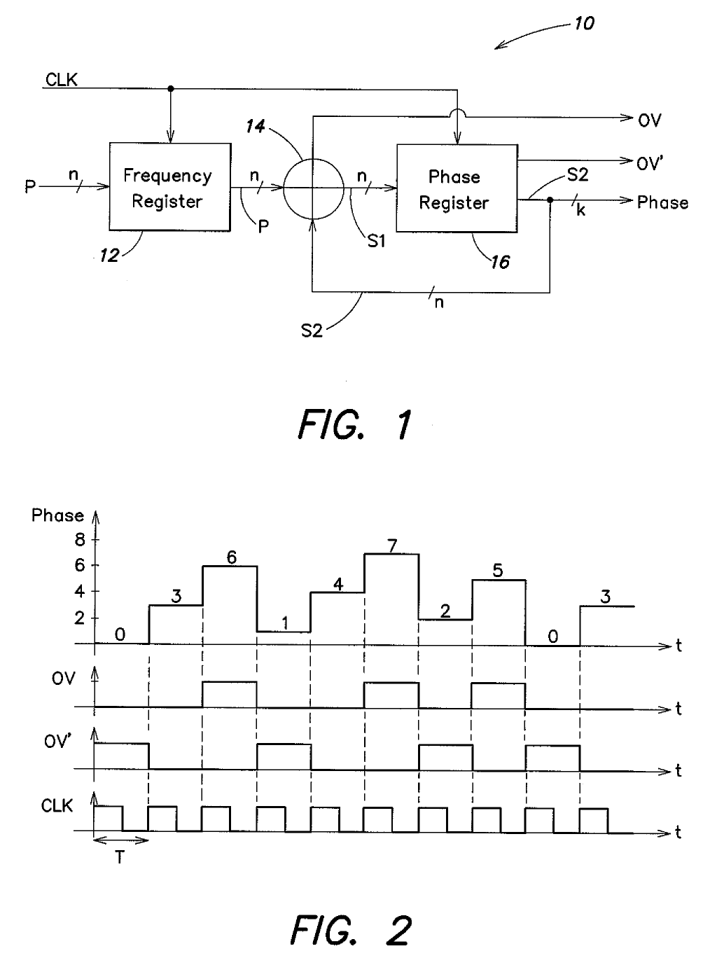

FIG. 1 shows a conventional embodiment of a phase accumulator 10 clocked by a clock signal CLK. Respectively call T_{CLK} and f_{CLK} the period and the frequency of clock signal CLK. Phase accumulator 10 comprises a first storage unit 12 (Frequency Register) in which a binary signal P is stored. Signal P comprises a number n of bits and will be called phase increment hereafter. Storage unit 12 provides phase increment P at the rate of clock signal CLK to a first input of an adder 14. Adder 14 provides a binary signal S1, comprising n bits, which is stored in a second storage unit 16 (Phase Register). Adder 14 further provides a one-bit binary signal Ov, called the first overflow bit. Signal S1 may take 2ⁿ different values. For each cycle of clock signal CLK, second storage unit 16 provides a signal S2 which is equal to the last value of signal S1 stored in second storage unit 16. Signal S2 is provided to a second input of adder 14. Storage unit 16 further provides a one-bit binary signal Ov′, called the second overflow bit. Phase accumulator 10 provides a binary signal Phase which corresponds to the k most significant bits of signal S2, with k being possibly equal to n.

The operation of phase accumulator 10 is the following: for each clock cycle, phase increment P is added to signal S2, that is, to the last value of signal S1, and the new obtained value of signal S1 is stored in storage unit 16. Considering that signal S1 is initially null, for each clock cycle of index i, the new value S1(i) of signal S1 is obtained by the following relation:

S1(i)=iP modulo 2ⁿ (1)

Signal S1, and thus signal Phase, increases “stepwise” then abruptly decreases each time signal S1 should reach, at the next clock cycle, a value greater than or equal to 2ⁿ. The decrease of signal S1 or S2 is called overflow in the following description. For each overflow of signal S1, first overflow bit Ov is set to “1”, for example, during a clock cycle. For each overflow of signal S2, second overflow bit Ov′ is set to “1”, for example, during a clock cycle. Second overflow bit Ov′ thus is substantially one clock cycle behind first overflow bit Ov.

Respectively call f_{OUT} and T_{OUT} the average frequency and the average frequency of second overflow bit Ov′. Frequency f_{OUT} is provided by the following relation:

$${f}_{OUT} = \frac{P}{{2}^{n}} {f}_{CLK} \qquad ( 2 )$$

FIG. 2 illustrates the variation of signals Phase, Ov, Ov′, and CLK of phase accumulator 10 of FIG. 1 in the case where phase increment P, n, and k are equal to 3. Signal Phase can thus take 8 different values, noted from 0 to 7. Signal Phase increases “stepwise” by decreasing on each exceeding of maximum value 7. In the example of FIG. 2, average frequency f_{OUT} Of second overflow bit Ov′ is equal to 3f_{CLK}/8.

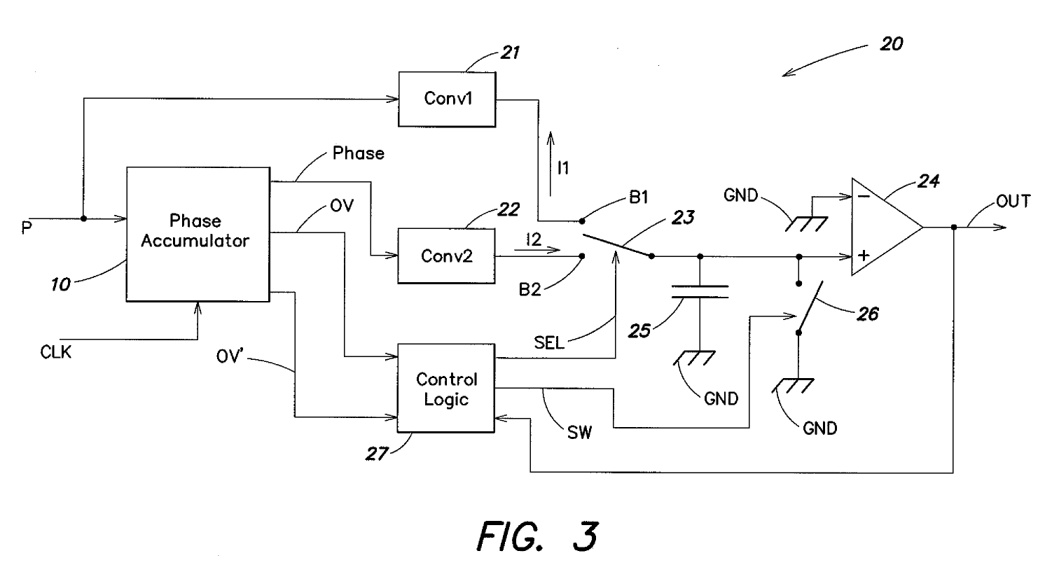

FIG. 3 shows a conventional embodiment of a digital synthesizer 20 using phase accumulator 10 of FIG. 1. Such an example of a digital synthesizer is described in publication “A low-jitter phase-interpolation DDS using dual-slope integration” by Hsin-Chuan Chen and Jen-Shiun Chiang (IEICE Electronics Express, Vol. 1, N^{o} 12, 333-338).

Frequency synthesizer 20 comprises a first conversion unit 21 (Conv1) receiving phase increment P and providing a terminal B1 with a current I1 having its intensity depending on phase increment P and which is, for example, proportional to phase increment P. Frequency synthesizer 20 comprises a second conversion unit 22 (Conv2) receiving signal Phase and providing a terminal B2 with a current I2 having its intensity depending on signal Phase and decreasing when signal Phase increases. A switch 23 controlled by a signal SEL is capable of connecting terminal B1 or terminal B2 to the positive input (+) of a comparator 24. The negative input (−) of comparator 24 is connected to ground GND. Comparator 24 provides a signal OUT corresponding to a sequence of pulses at frequency f_{OUT}. A capacitor 25 is provided between the positive input (+) of comparator 24 and of ground GND. A switch 26 controlled by a signal SW is provided across capacitor 25. A control unit 27 (Control Logic) receives overflow bits Ov and Ov′, signal OUT and provides signals SEL and SW.

The operation of synthesizer 20 is the following: when first overflow bit Ov is at “1”, switch 23 connects terminal B2 to the positive input (+) of comparator 24. Capacitor 25 is then charged by current I2 having its intensity decreasing as signal Phase increases. The voltage across capacitor 25 being positive, signal OUT is low. When second overflow bit Ov′ is at “1”, at the next clock cycle, switch 23 connects terminal B1 to the positive input (+) of comparator 24. Capacitor 25 is then discharged by current I1 having a constant intensity which depends on phase increment P. Signal OUT switches from the low level to the high level when capacitor 25 is fully discharged. The switching time of signal OUT depends on the duration of the discharge of capacitor 25, and thus on the intensity of current I2 with which it has been charged at the preceding clock cycle. The times of occurrence of the rising edges of signal OUT are thus modulated and are exactly separated by time period T_{OUT}.

A disadvantage of synthesizer 20 is that, because of its operation, output frequency f_{OUT} is necessarily lower than half the frequency of clock signal f_{CLK}.

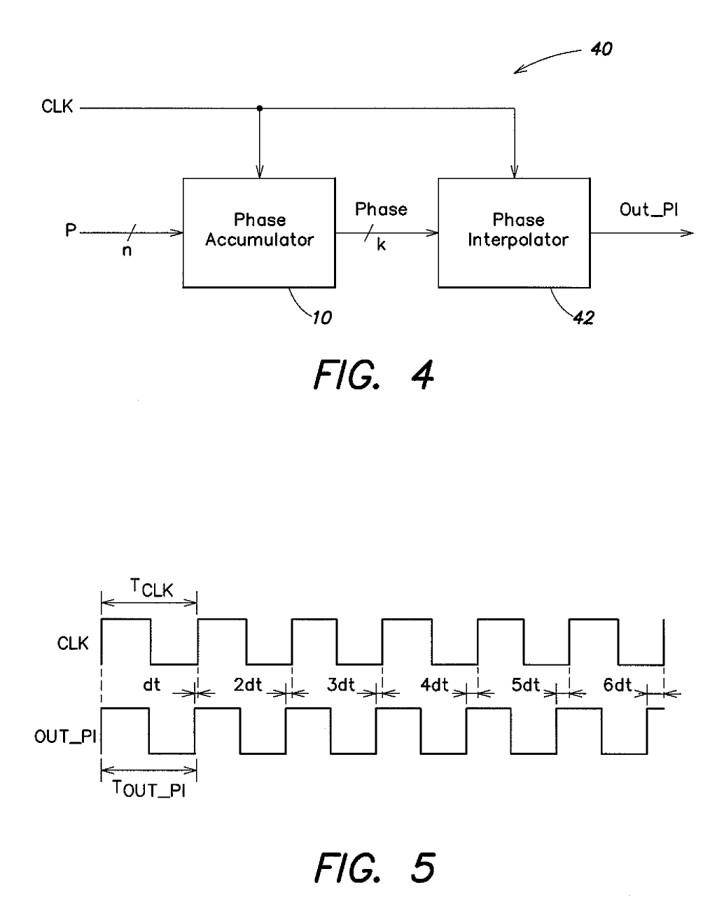

FIG. 4 schematically shows an embodiment of a frequency synthesizer 40 according to the present invention using a phase accumulator 10, for example, the phase accumulator previously described in relation with FIG. 1. Synthesizer 40 comprises a phase interpolator 42, receiving clock signal CLK and signal Phase and providing a one-bit binary signal OUT_PI, corresponding to a periodic sequence of pulses having a period T_{OUT}_{_{—}}_{PI} and a frequency f_{OUT}_{_{—}}_{PI}. Conversely to conventional frequency synthesizers using a phase accumulator, the present frequency synthesizer uses signal Phase provided by the phase accumulator and not second overflow bit Ov′ to determine signal OUT_PI having the desired frequency f_{OUT}_{_{—}}_{PI}.

FIG. 5 illustrates the operating principle of synthesizer 40 of FIG. 4. In FIG. 5, clock signal CLK and an example of the variation of signal OUT_PI provided by synthesizer 40 have been shown. Generally, phase accumulator 10 increases for each clock cycle signal Phase of phase increment P up to the overflow. In the interval during which signal Phase increases, phase interpolator 42 provides, for each successive pulse of clock signal CLK, a pulse of signal OUT_PI which is phase-shifted with respect to the corresponding pulse of clock signal CLK by a positive or negative phase shift, which depends on signal Phase, and which is for example proportional to signal Phase. Thereby, in an increase of signal Phase up to the overflow, the phase shift applied by phase interpolator 42 increases by a constant phase shift step. This translates as the obtaining of a signal OUT_PI which is generally shifted in frequency with respect to signal CLK.

The phase shift applied by phase interpolator 42 thus follows the variation of signal Phase and in particular decreases, in absolute value, after each overflow of signal Phase. After an overflow, phase interpolator 42 cannot take into account a pulse of clock signal CLK or a value of signal Phase, or use again the last pulse of clock signal CLK to ensure the regularity in the provision of the pulses of signal OUT_PI.

Period T_{OUT}_{_{—}}_{PI} of signal OUT_PI is provided by the following relation:

T_{OUT}_{_{—}}_{PI}=T_{CLK}+dt (3)

where dt may be positive or negative according to the operation of phase interpolator 42. The absolute value of increment dt is linked to the operating parameters of phase accumulator 10 according to the following relation:

$$\vert dt \vert = \frac{P}{{2}^{n}} {T}_{CLK} \qquad ( 4 )$$

Frequency f_{OUT}_{_{—}}_{PI} is then provided by the following relation:

$${f}_{OUT\_PI} = \frac{{f}_{CLK}}{1 \pm \frac{P}{{2}^{n}}} \qquad ( 5 )$$

The frequency synthesizer according to an embodiment is thus capable of providing, from a clock signal CLK, a periodic signal having a frequency f_{OUT}_{_{—}}_{PI} that can be lower than, greater than, or equal to frequency f_{CLK} of clock signal CLK. The frequency synthesizer according to the present invention has the advantage that it can be almost completely formed of digital components except, possibly, for certain elements of phase interpolator 42.

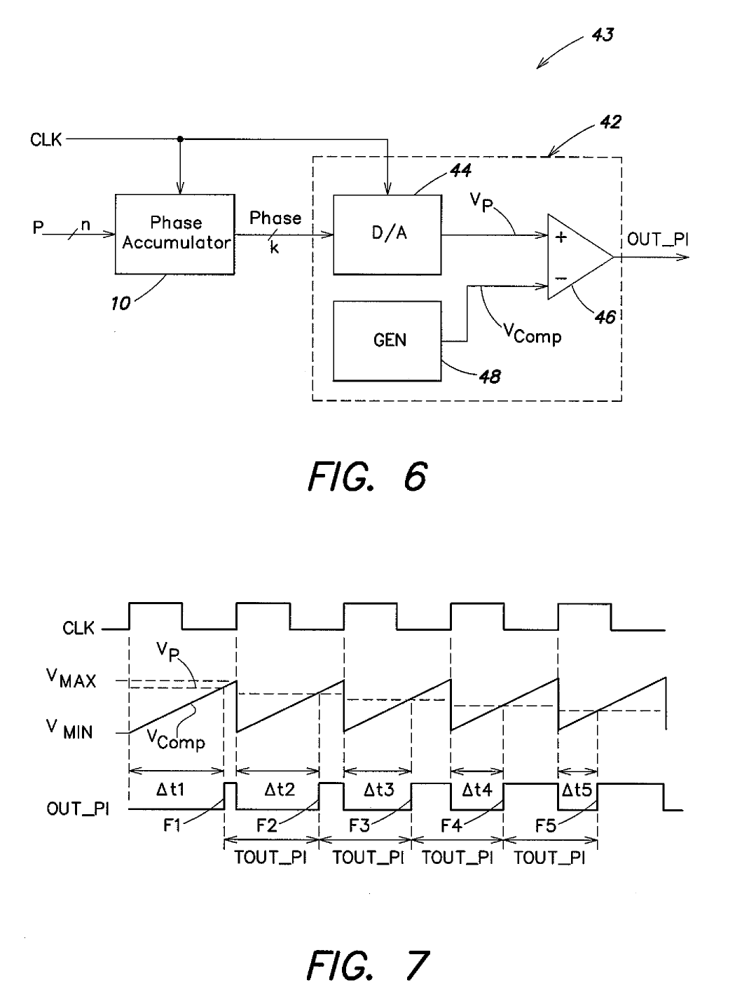

FIG. 6 shows an example of a frequency synthesizer 43 having the general structure of the frequency synthesizer of FIG. 4 and for which a more detailed embodiment of phase interpolator 42 is shown. Phase interpolator 42 comprises a digital-to-analog converter 44 (D/A) rated by clock signal CLK and receiving signal Phase. Converter 44 converts signal Phase into an analog voltage V_{P} which is provided to the positive input (+) of a comparator 46. The negative input (−) of comparator 46 receives a periodic sawtooth voltage V_{COMP} at frequency f_{CLK} provided by a generator 48 (GEN). Comparator 46 provides signal OUT_PI corresponding to a pulse sequence (of variable durations) provided at frequency f_{OUT}_{_{—}}_{PI}. Voltage V_{COMP} varies between a minimum voltage V_{MIN} and a maximum voltage V_{MAX}. The maximum voltage capable of being provided by converter 44 is equal to V_{MAX} and the minimum voltage capable provided by converter 44 is equal to V_{MIN}.

FIG. 7 illustrates the operating principle of frequency synthesizer 43 of FIG. 6. For each clock cycle, phase accumulator 10 provides a new value of signal Phase. In the present example, this translates as the provision by converter 44 of a new value of voltage V_{P} which decreases by a constant step. Simultaneously, for each clock cycle, generator 48 provides a voltage V_{COMP} corresponding to an increasing ramp. The time of occurrence of the rising edge of a pulse of signal OUT_PI corresponds to the time at which voltage V_{COMP} reaches voltage V_{P}. As an example, five successive rising edges F1 to F5 of signal OUT_PI are shown. Each rising edge of signal OUT_PI is shifted by a time period Δt1, Δt2, Δt3, Δt4, and Δt5 from the corresponding rising edge of clock signal CLK.

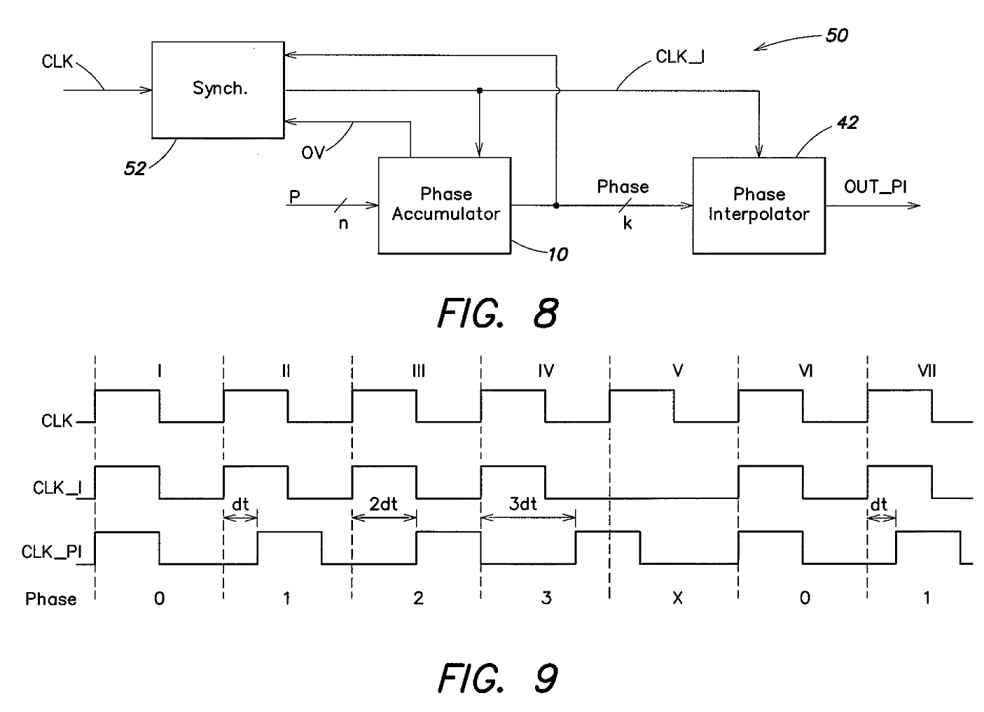

FIG. 8 shows an embodiment of a synthesizer 50 for which the elements taking part in the management of the overflows of phase accumulator 10 have been shown. Frequency synthesizer 50 comprises a synchronization unit 52 (Synch.) receiving clock signal CLK, first overflow bit Ov, and signal Phase and providing a modified clock signal CLK_I to phase accumulator 10 and to phase interpolator 42. Modified clock signal CLK_I enables simply ensuring the regularity of signal OUT_PI on overflows of signal Phase.

FIG. 9 illustrates an example of the variation of characteristic signals of frequency synthesizer 50 of FIG. 8 on overflow of phase accumulator 10. In the present example, the parameters of phase accumulator 10 are the following: n and k are equal to 2 and P is equal to 1. Values 0, 1, 2, and 3 of signal Phase respectively correspond to phase shifts by 0, T_{CLK}/4, T_{CLK}/2, and 3T_{CLK}/4. Seven successive cycles I to VII of clock cycle CLK are shown. For the first four cycles of clock signal CLK, signal Phase successively takes values 0, 1, 2, and 3, which causes a phase shift of the rising edge of signal OUT_PI with respect to the rising edge of the corresponding clock signal CLK successively by 0, T_{CLK}/4, T_{CLK}/2, and 3T_{CLK}/4. At cycle IV, first overflow bit Ov is set to “1”. At the next cycle (cycle V), synchronization unit 52 transmits the pulse of clock signal CLK neither to phase accumulator 10 nor to phase interpolator 42, and modified clock signal CLK_I remains at “0”. The overflow of phase accumulator 10 then occurs at cycle VI. This enables ensuring a regularity in the provision of the pulses of signal OUT_PI. At cycle VI, phase accumulator 10 provides signal Phase at value 0 and phase integrator 42 provides a pulse of signal OUT_PI which is not phase-shifted with respect to the corresponding pulse of signal CLK_I.

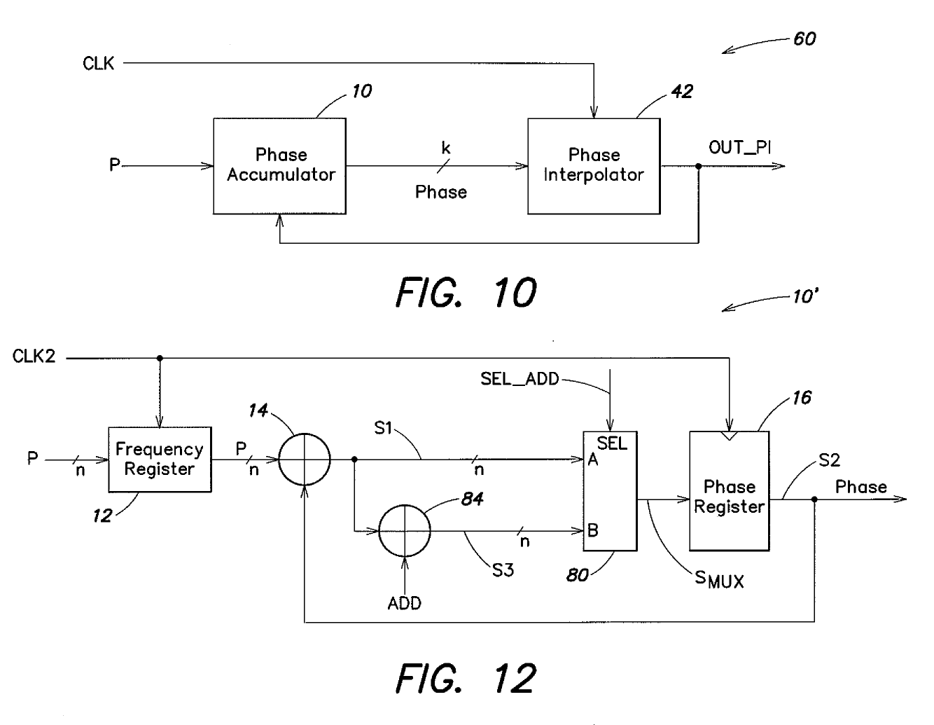

FIG. 10 shows another embodiment of frequency synthesizer 60 simply enabling taking into account the overflows of signal Phase. For frequency synthesizer 60, phase accumulator 10 is not rated by clock signal CLK but by signal OUT_PI. This enables ensuring for the values of signal Phase provided by phase accumulator 10 to always be provided at the right time. Interpolator 42 may further comprise a synchronization unit (not shown) receiving clock signal CLK and providing a modified clock signal from which signal OUT_PI is obtained.

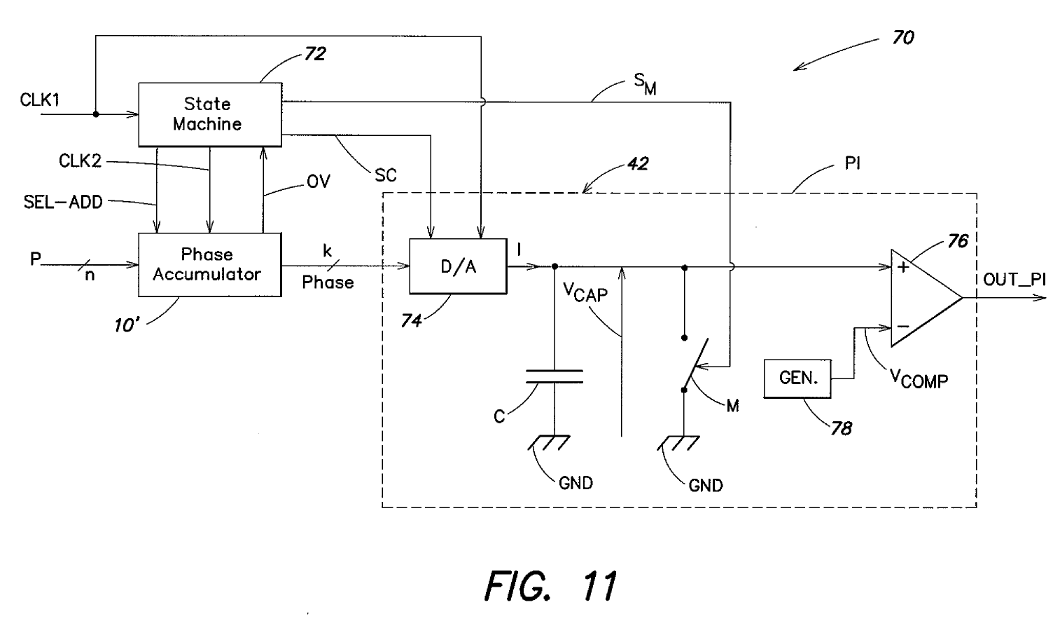

FIG. 11 shows another embodiment of a frequency synthesizer 70. As will be described in further detail hereafter, phase accumulator 10′ has a structure slightly different from that previously described for phase accumulator 10 in relation with FIG. 1. Frequency synthesizer 70 comprises a finite state machine 72 clocked by a clock signal CLK1. Phase interpolator 42 is also rated by clock signal CLK1. Finite state machine 72 provides a modified clock signal CLK2 from first clock signal CLK1. As will be described in further detail hereafter, signal CLK2 partly corresponds to a periodic sequence of pulses having a smaller frequency than clock signal CLK1. Modified clock signal CLK2 rates phase accumulator 10′. Phase accumulator 10′ provides first overflow bit Ov to a finite state machine 72. Finite state machine 72 also provides a signal SEL_ADD to phase accumulator 10′. Signal SEL_ADD is, for example, a single-bit binary signal. Phase interpolator 42 comprises a digital-to-analog converter 74 (D/A) receiving signal Phase and a signal S_{C} provided by finite state machine 72. Signal S_{C} is, for example, a one-bit binary signal. Converter 74 provides a current I having its amplitude depending on the value of signal Phase and of signal S_{C}. Current I provided by converter 74 is likely to take 2ⁿ values, noted L0 to L2ⁿ−1. Current I charges a capacitor C having one terminal connected to the output of converter 74 and having its other terminal connected to a source of a reference voltage, for example, ground GND. The voltage across capacitor C is designated with reference V_{CAP}. A switch M, for example, a MOS transistor, is assembled in parallel across capacitor C and is controlled by a signal S_{M} provided by finite state machine 72. Voltage V_{CAP} is applied to a positive terminal (+) of a comparator 76. The negative terminal (−) of comparator 76 receives a constant voltage V_{COMP} provided by a voltage generator 78 (GEN). The output of comparator 76 corresponds to signal OUT_PI.

FIG. 12 shows an embodiment of phase accumulator 10′. Phase accumulator 10′ comprises the same elements as phase accumulator 10 shown in FIG. 1. Phase accumulator 10′ further comprises a multiplexer 80 receiving, on a first input (A), signal S1 provided by adder 14 and providing a signal S_{MUX} to storage unit 16. Further, phase accumulator 10′ comprises an adder 84 receiving, on a first input, signal S1 provided by adder 14 and, on a second input, a signal ADD equal to value “1”. Adder 84 provides a signal S3 to a second input (B) of multiplexer 80. Multiplexer 80 comprises a selection terminal receiving signal SEL_ADD provided by finite state machine 72. As an example, when signal SEL_ADD is at “0”, signal S_{MUX} is equal to S1 and when signal SEL_ADD is at “1”, signal S_{MUX} is equal to S3.

The operation of frequency synthesizer 70 will now be described for a specific example in which P is equal to 1 and n and k are equal to 2. Current I provided by converter 72 is likely to take 4 values, noted L0 to L3. Further, current L0 corresponds to the null current, current L2 is equal to two thirds of current L3, and current L1 is equal to one third of current L3.

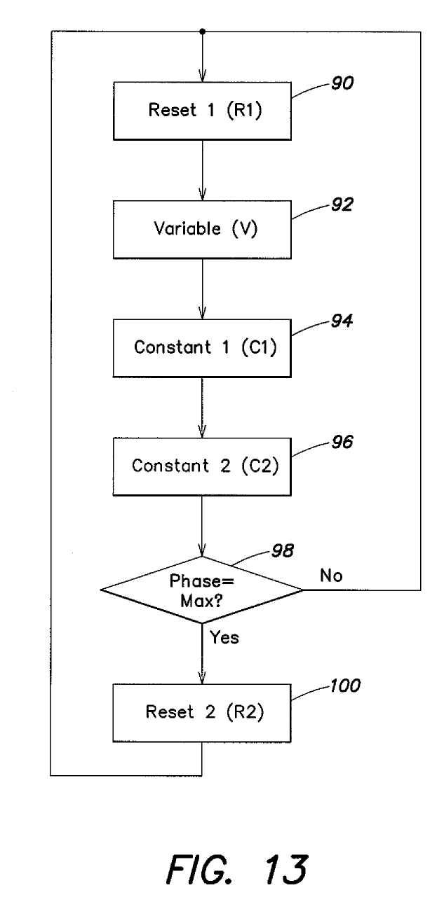

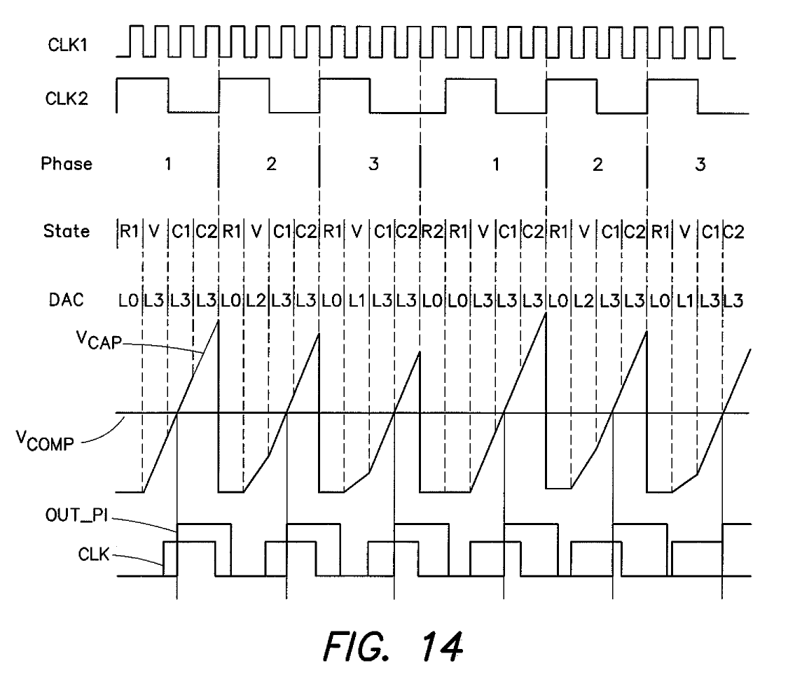

FIG. 13 illustrates an example of an operating method of finite state machine 72. In this embodiment, finite state machine 72 is likely to occupy one state out of five, respectively called “R1”, “V”, “C1”, “C2”, and “R2” hereafter. Finite state machine 72 switches from one state to another state at the frequency of clock signal CLK1. In the present example, modified clock signal CLK2 provided by finite state machine 72 has a frequency which is approximately four times smaller than the frequency of clock signal CLK1.

At step 90, finite state machine 72 is at state “R1” (Reset1). It then causes the turning-on of switch M, causing the discharge of capacitor C. Further, converter 74 is controlled by signal S_{C} so that current I is equal to L0. Further, if an overflow will occur at the next cycle of modified clock signal CLK2, that is, if first overflow bit Ov is at “1”, finite state machine 72 sets signal SEL_ADD to “1”. In the opposite case, it sets signal SEL_ADD to “0”. The method carries on at step 92.

At step 92, finite state machine 72 switches to state “V” (Variable). It causes the turning-off of switch M, causing the charge of capacitor C with the current. Finite state machine 72 controls, with signal S_{C}, converter 74 so that current I is at a value L1, L2, or L3 according to the value of signal Phase. As an example, current I is at L3 when signal Phase is at 1, current I is at L2 when signal Phase is at 2, and current I is at L1 when signal Phase is at 3. The method carries on at step 94.

At step 94, finite state machine 72 switches to state “C1” (Constant1). Finite state machine 72 causes the turning-off of switch M, causing the charge of capacitor C with current I, and it further controls converter 74 so that current I is at value L3. The method carries on at step 96.

At step 96, finite state machine 72 switches to state “C2” (Constant2). Finite state machine 72 causes the turning-off of switch M, causing the charge of capacitor C with current I, and it further controls converter 74 so that current I is at value L3. The process carries on at step 98.

At step 98, the finite state machine determines from the value of first overflow bit Ov whether an overflow will occur at the next cycle of modified clock signal CLK2. If not, the method carries on at step 90. If so, the process carries on at step 100.

At step 100, finite state machine 72 switches to state “R2” (Reset2). It then causes the turning-on of switch M, causing the discharge of capacitor C. Further, converter 74 is controlled so that current I is equal to L0. Further, finite state machine 72 delays modified clock signal CLK2 by a cycle of clock CLK1. The process then returns to step 90.

FIG. 14 shows an example of variations of characteristic signals of synthesizer 70 of FIG. 11. A periodic signal CLK superposed to signal OUT_PI and having its frequency f_{CLK} equal to the one quarter of the frequency of signal CLK1 has been shown. As an example, the frequency of clock signal CLK1 is 2 GHz. According to the value of signal Phase, voltage V_{CAP} across capacitor C increases more or less rapidly and reaches comparison voltage V_{COMP} at times regularly spaced apart at frequency f_{OUT}_{_{—}}_{PI}. The expression of frequency f_{OUT}_{_{—}}_{PI} for synthesizer 70 can be deduced from relation (5), considering that 4(2^{N}−1) values of signal Phase are used to describe 360°:

$${f}_{OUT\_PI} = \frac{{f}_{CLK 2}}{1 + \frac{P}{4 \times ( {2}^{n} - 1 )}} \qquad ( 6 )$$

where f_{CLK2} is the frequency of clock signal CLK2.

According to a variation of the previously-described embodiment, a buffer memory may be provided on the transmission line of signal Phase between phase accumulator 10 and phase interpolator 42, a buffer memory may be provided on the transmission line of signal S_{C} between finite state machine 72 and phase interpolator 42 and on the transmission line of signal S_{M} between finite state machine 72 and phase interpolator 42. Each buffer delays the transmission of the signal that it stores, for example, by one cycle of clock CLK1. In this case, finite state machine 72 may receive second overflow bit Ov′ instead of first overflow bit Ov and may determine whether an overflow of signal Phase occurs based on second overflow bit Ov′ which has the advantage of being generally better stabilized than first overflow bit Ov.

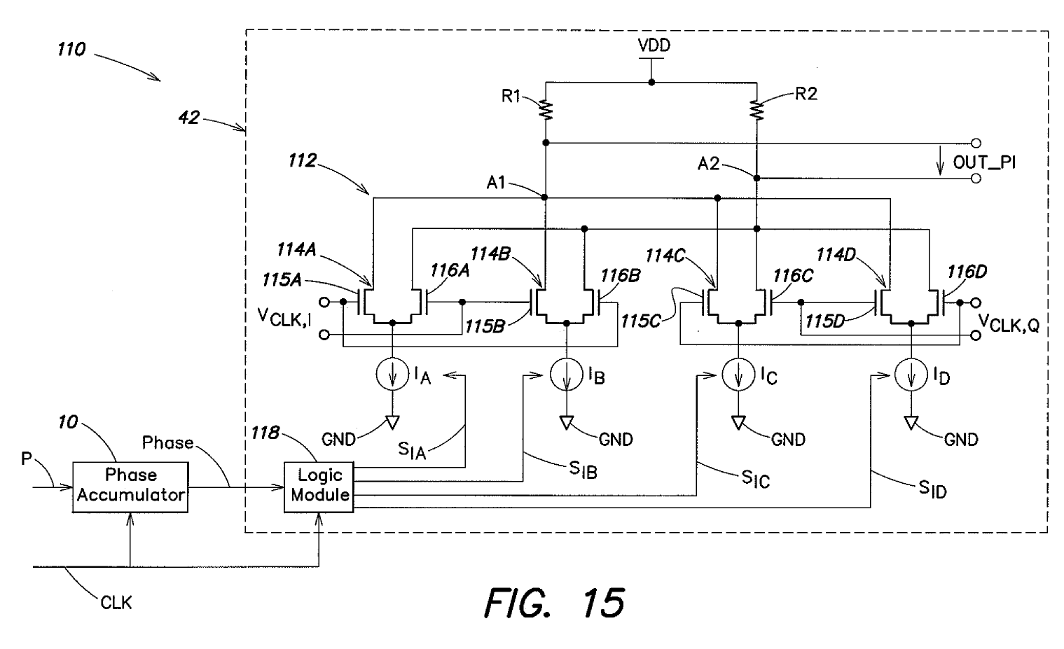

FIG. 15 shows another embodiment of a digital frequency synthesizer 110. In this embodiment, phase interpolator 42 comprises an interpolation circuit 112 such as that described in publication “A 10-Gb/s CMOS Clock and Data Recovery Circuit With an Analog Phase Interpolator” by R. Kreienkamp, U. Langmann, Ch. Zimmermann, T. Aoyama, and H. Siedhoff (IEEE Journal of solid-state circuits, vol. 40, N^{o} 3, March 2005, pp. 736-743).

Circuit 112 comprises four differential pairs 114A to 114D, each comprising a first MOS transistor 115A to 115D and a second MOS transistor 116A to 116D. For each differential pair, the drain of transistor 115A to 115D is connected to a node A1 and the drain of transistor 116A to 116D is connected to a node A2. Further, for each differential pair, the sources of transistors 115A to 15D and 116A to 116D are connected to a terminal of a current source I_{A} to I_{D} having its other terminal connected to a source of a first reference voltage, for example, ground GND. Node A1 is connected to a source of a second reference voltage VDD via a resistor R1. Node A2 is connected to source VDD via a resistor R2. The voltage between nodes A1 and A2 corresponds to signal OUT_PI.

A clock signal V_{CLK,I} is applied between the gate of transistor 115A and the gate of transistor 116A, and the clock signal complementary to V_{CLK,I} (that is, phase-shifted by 180° with respect to V_{CLK,I}) between the gate of transistor 115B and the gate of transistor 116B. A clock signal V_{CLK,Q} phase-shifted by 90° with respect to signal V_{CLK,I} is applied between the gate of transistor 115C and the gate of transistor 116C, and the clock signal complementary to V_{CLK,Q} (that is, phase-shifted by 180° with respect to V_{CLK,Q}) is applied between the gate of transistor 115D and the gate of transistor 116D. Signals V_{CLK,I} and V_{CLK,Q} may correspond to pulse sequences, to sinusoidal signals, or to triangular signals.

Phase interpolator 42 also comprises a control unit 118 (Logic Module), rated by clock signal CLK, receiving signal Phase and providing control signals S_{IA} to S_{ID} to current sources I_{A} to I_{D}. The frequency of signal V_{CLK,I} is equal to an integral multiple, possibly equal to 1, of the frequency of clock signal CLK.

Differential pairs 114A to 114D are driven by clock signals in quadrature. The sum of currents I_{A} to I_{D} is constant so that the peak-to-peak amplitude of signal OUT_PI remains constant. Circuit 112 provides a voltage OUT_PI corresponding to a clock signal phase-shifted with respect to signal V_{CLK,I}, the value of the phase shift being imposed by the values of current I_{A}, I_{B}, I_{C}, and I_{D}. Currents I_{A} and I_{D} are in fact integrated by the stray capacitances of the MOS transistors or by capacitors, not shown, provided in parallel with resistors R1 and R2.

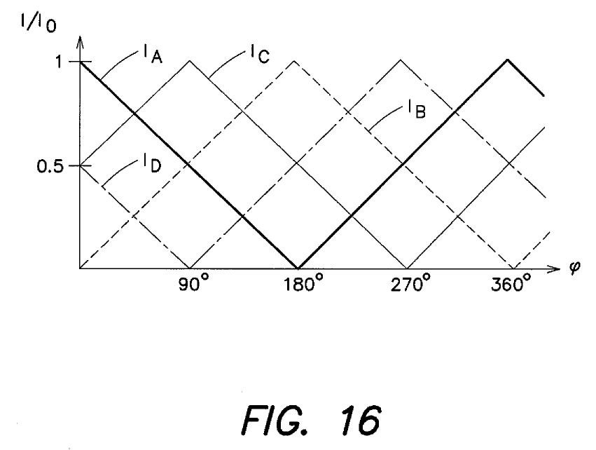

FIG. 16 illustrates the curves of variation of currents I_{A} to I_{D} according to the phase shift of the signal OUT_PI desired for interpolation circuit 112.

In operation, the values of currents I_{A} to I_{D} are controlled by the corresponding control signals S_{IA} to S_{ID} which are themselves determined by control unit 118 based on signal Phase. For each new value of signal Phase, control unit 118 determines new values of control signals S_{IA} to S_{ID} so that the phase shift of signal OUT_PI with respect to signal V_{CLK,I} depends on signal Phase and is, for example, proportional to signal Phase.

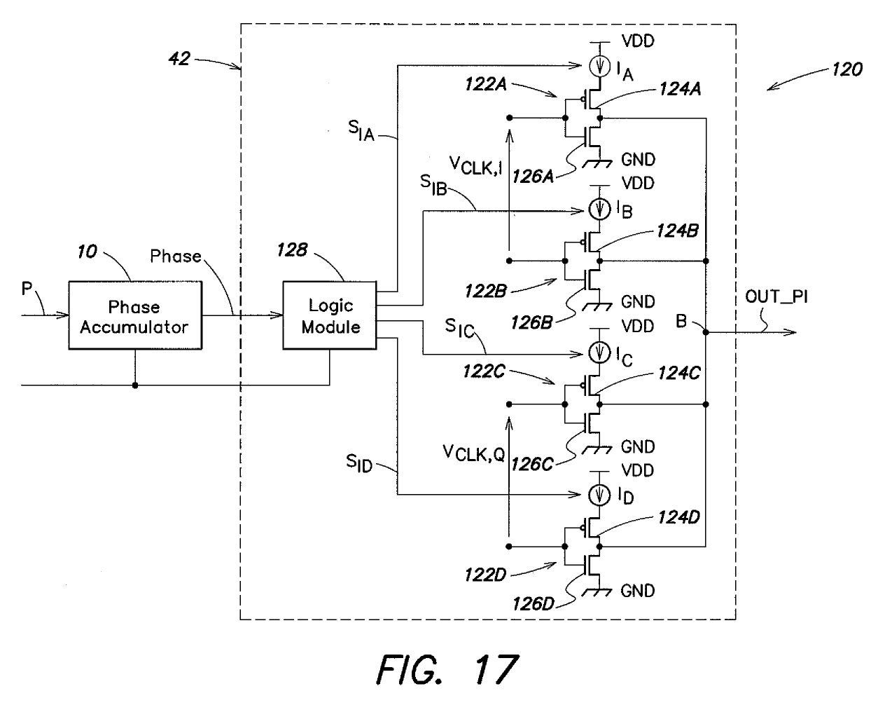

FIG. 17 shows another embodiment of a digital frequency synthesizer 120. Phase interpolator 42 comprises four CMOS inverters 122A to 122D, each comprising a P-channel MOS transistor 124A to 124D and an N-channel MOS transistor 126A to 126D. For each CMOS inverter, the drain of transistor 124A to 124D and the drain of transistor 126A to 126D are connected to a node B. For each CMOS inverter, the source of transistor 124A to 124D is connected to a terminal of a current source I_{A} to I_{D} having its other terminal connected to a source of a first reference voltage VDD. For each CMOS inverter, the drain of transistor 126A to 126D is connected to a source of a second reference voltage, for example, ground GND. The voltage at node B corresponds to signal OUT_PI. Further, for each CMOS inverter, the gate of transistor 124A to 124D is connected to the gate of the associated transistor 126A to 126D.

A clock signal V_{CLK,I} is applied between the gates of transistors 124A and 126A and the gates of transistors 124B and 126B, and a clock signal V_{CLK,Q}, phase-shifted by 90° with respect to signal V_{CLK,I}, is applied between the gates of transistors 124C and 126C and the gates of transistors 124D and 126D. Signals V_{CLK,I} and V_{CLK,Q} may correspond to pulse sequences, to sinusoidal signals, to triangular signals.

Phase interpolator 42 also comprises a control unit 128 (Logic Module), rated by clock signal CLK, receiving signal Phase and providing control signals S_{IA} to S_{ID} to current sources I_{A} to I_{D}. The frequency of signal V_{CLK,I} is equal to an integral multiple, possibly equal to 1, of the frequency of clock signal CLK.

CMOS inverters 122A to 122D are driven by clock signals in quadrature. The sum of currents I_{A} to I_{D} is constant so that the peak-to-peak amplitude of signal OUT_PI remains constant. Signal OUT_PI corresponds to a clock signal phase shifted with respect to signal V_{CLK,I}, the value of the phase shift being imposed by the values of currents I_{A}, I_{B}, I_{C}, and I_{D}. Currents I_{A} and I_{D} are in fact integrated by the stray capacitances of the MOS transistors.

In operation, the values of currents I_{A} to I_{D} are controlled by the corresponding control signals S_{IA} to S_{ID} which are themselves determined by control unit 128 based on signal Phase. For each new value of signal Phase, control unit 128 determines new values of control signals S_{IA} to S_{ID} so that the phase shift of signal OUT_PI with respect to signal V_{CLK,I} depends on signal Phase and is, for example, proportional to signal Phase.

In the embodiments previously described in relation with FIGS. 15 and 17, the number of differential pairs or of CMOS inverters may be greater than 4 while corresponding to a power of 2.

Specific embodiments of the present invention have been described. Various alterations, modifications, and improvements will occur to those skilled in the art. In particular, phase interpolator 42 may be formed with MOS transistors and finite state machine 72 will then be adapted to this structure.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A digital frequency synthesizer receiving a first signal corresponding to a periodic sequence of first pulses at a first frequency and providing a second signal corresponding to a periodic sequence of second pulses at a second frequency, comprising:
a first circuit clocked by a third signal corresponding to a sequence of third pulses and obtained from the first signal, the first circuit providing a fourth digital signal which, for any set of third successive pulses, increases on each pulse and decreases at the end of said set or decreases on each pulse and increases at the end of said set; and
a second circuit receiving the first and fourth signals and providing, for each first pulse from among some at least of the first pulses, a second pulse which is shifted with respect to said first pulse by a duration which varies in the same way as the fourth signal or inverse to the fourth signal.

2. The synthesizer of claim 1, wherein the second circuit comprises:
a third circuit providing a fifth analog signal which depends on the fourth signal;
a source of a sixth analog signal; and
a comparator receiving the fifth and sixth signals and providing the second signal.

3. The synthesizer of claim 2, wherein the first and third signals are identical, wherein the source is capable of providing the sixth analog signal in the form of a first sawtooth voltage at the rate of the first signal, and wherein the third circuit comprises a digital-to-analog converter providing, at the rate of the first signal, the fifth signal in the form of a second stepped voltage which depends on the fourth signal.

4. The synthesizer of claim 2, wherein the source is capable of providing the sixth signal in the form of a constant voltage and wherein the third circuit comprises:
a digital-to-analog converter providing a current which at least partly depends on the fourth signal;
a capacitor charged by the current; and
a switch assembled in parallel across the capacitor, the fifth signal corresponding to the voltage across the capacitor.

5. The synthesizer of claim 4, comprising a finite state machine clocked by the first signal and capable of:
causing, in a first state, the turning-on of the switch to discharge the capacitor; and
causing, in a second state, the turning-off of the switch and controlling the converter to charge the capacitor with said current.

6. The synthesizer of claim 1, wherein the first circuit comprises:
a first storage unit providing, at the clock rate of the third signal, a seventh digital signal;
an adder receiving the seventh digital signal and an eighth signal and providing a ninth digital signal corresponding to the sum of the seventh and eighth signals; and
a second storage unit receiving the ninth signal and providing, at the clock rate of the third signal, the eighth signal which corresponds to the last value of the stored ninth signal, the fourth signal being obtained from the eighth signal.

7. The synthesizer of claim 1, wherein the first circuit comprises:
a first storage unit providing, at the clock rate of the third signal, a seventh digital signal;
a first adder receiving the seventh digital signal and an eighth signal and providing a ninth digital signal corresponding to the sum of the seventh and eighth signals;
a second adder receiving the ninth signal and a tenth digital signal, the tenth signal corresponding to a constant value, the second adder providing an eleventh signal corresponding to the sum of the seventh, eighth, and tenth signals;
a multiplexer receiving the ninth signal and the eleventh signal and comprising a selection terminal receiving a twelfth signal provided by the finite state machine and providing a thirteenth signal equal to the eighth signal or to the eleventh signal according to the value of the twelfth signal; and
a second storage unit receiving the thirteenth signal and providing, at the rate of the third signal, the eighth signal which corresponds to the last value of the stored thirteenth signal, the fourth signal being obtained from the eighth signal.

8. The synthesizer of claim 1, wherein the second circuit comprises:
N current sources, N being an integer corresponding to a power of two, each current source providing a current which depends on the fourth signal; and
at least N transistors, each transistor having a first main terminal connected to one of the N current sources and a second main terminal connected to an output node, the transistor being controlled by one of N oscillating signals, the N oscillating signals being phase-shifted with respect to one another, the second signal being provided to said output node.

9. A method for providing, from a first signal corresponding to a periodic sequence of first pulses at a first frequency, a second signal corresponding to a periodic sequence of second pulses at a second frequency, comprising the steps of:
providing, at the rate of a third signal corresponding to a sequence of third pulses and obtained from the first signal, and providing a fourth digital signal which, for any set of third successive pulses, increases on each pulse and decreases at the end of said set; and
providing, for each first pulse from among some at least of the first pulses, a second pulse shifted with respect to said first pulse by a duration which varies in the same way as the fourth signal or inverse to the fourth signal.

10. The method of claim 9, further comprising the steps of:
providing a fifth analog signal which depends on the fourth signal; and
providing the second signal based on the comparison of the fifth signal and of a sixth analog signal.

11. The method of claim 10, further comprising the steps of:
converting the fourth signal into a current; and
charging a capacitor with said current, the fifth signal corresponding to the voltage across the capacitor and the sixth signal being a constant voltage.
